(19) United States
(12) Patent Application Publication
(10) Pub. No.: US 2026/0231812 A1
(43) Pub. Date: Aug. 6, 2026

(54) FUNCTIONAL ISOLATION FOR SMALL PACKAGE SIZES

(71) Applicant: TEXAS INSTRUMENTS INCORPORATED, DALLAS, TX (US)

(72) Inventors: Saminah CHAUDHRY, MCKINNEY, TX (US); Sylvester ANKAMAH-KUSI, MCKINNEY, TX (US); Usman CHAUDHRY, MCKINNEY, TX (US)

(21) Appl. No.: 19/042,991

(22) Filed: Jan. 31, 2025

(51) Int. Cl. H01L 21/56; H01L 23/00; H01L 23/31

(52) U.S. Cl. CPC H10W 74/019; H10W 74/111; H10W 70/09; H10W 70/60; H10W 70/6528; H10W 72/0198

(57) ABSTRACT

An integrated circuit includes a semiconductor die including a set of conductive pads on a given side of the die. The integrated circuit also includes a set of conductive bumps. A conductive bump of the set of conductive bumps has a first end and a second end, and the first end of the conductive bump is coupled to a respective pad of the set of conductive pads. The integrated circuit additionally includes a first passivation layer around the set of conductive bumps, a redistribution layer coupled to the second end of the conductive bump, a lead, and a second passivation layer around the lead. The integrated circuit further includes a conductive via coupled, in the second passivation layer, between the redistribution layer and the lead.

### TECHNICAL FIELD

This description relates to semiconductor packages with functional isolation and techniques for making semiconductor packages with functional isolation.

### BACKGROUND

Functional isolation ensures the proper functionality of an electrical system. Functional isolation is used in a variety of applications, for example, to protect signals from high ground potential differences, preventing signal inaccuracies. Different products and applications have varying target levels of functional isolation.

### SUMMARY

A first example is related to an integrated circuit. The integrated circuit includes a semiconductor die including a set of conductive pads on a given side of the die. The integrated circuit also includes a set of conductive bumps. A conductive bump of the set of conductive bumps has a first end and a second end, and the first end of the conductive bump is coupled to a respective pad of the set of conductive pads. The integrated circuit additionally includes a first passivation layer around the set of conductive bumps, a redistribution layer coupled to the second end of the conductive bump, a lead, and a second passivation layer around the lead. The integrated circuit further includes a conductive via coupled, in the second passivation layer, between the redistribution layer and the lead.

A second example is related to a method that includes attaching a carrier to a set of conductive bumps and to a first side of a semiconductor die that includes a set of conductive pads on the first side of the die. A conductive bump of the set of conductive bumps has a first end and a second end, and the first end of the conductive bump is coupled to a respective pad of the set of conductive pads. The method also includes forming a mold layer over the carrier and a second side of the semiconductor die. The method additionally includes removing the carrier from the mold layer and the semiconductor die. The method further includes forming a first passivation layer on the first side of the semiconductor die and a given side of the mold layer and forming a redistribution layer on a given side of the first passivation layer and coupled to the second end of the conductive bump. Additionally, the method includes forming a second passivation layer on the given side of the first passivation layer and a given side of the redistribution layer and forming a set of vias through the second passivation layer. A via of the set of vias has a first end and a second end coupled to the given side of the redistribution layer. The method also includes forming a set of leads in the second passivation layer. A lead of the set of leads is coupled to the first end of the via.

A third example is related to a method that includes attaching a tape substrate to a side of a semiconductor die having a set of conductive bumps extending from the side of the die. The tape substrate comprises a tape layer, a solder mask, a set of vias, and a set of leads, in which a via of the set of vias is coupled between the conductive bump and a lead of the set of leads. The solder mask surrounds the set of vias in a respective layer of the tape substrate. The method also includes applying a molding compound to the tape substrate and a top side of the semiconductor die to provide a packaged semiconductor device.

### BRIEF DESCRIPTION OF THE DRAWINGS

FIG. 1 illustrates a cross-sectional view of a first example integrated circuit.

FIG. 2 illustrates a cross-sectional view of a second example integrated circuit.

FIG. 3 illustrates a cross-sectional view of a third example integrated circuit.

FIG. 4 illustrates a first method for formation of an integrated circuit.

FIGS. 5A-E illustrate steps in the formation of an example integrated circuit.

FIGS. 6A-E illustrate additional steps in the formation of an example integrated circuit.

FIG. 7 illustrates a cross-sectional view of a fourth example integrated circuit.

FIG. 8 illustrates a second method for formation of an integrated circuit

FIG. 9 illustrates a method for formation of a tape substrate of an integrated circuit.

FIGS. 10A-F illustrate steps in the formation of an example tape substrate.

FIGS. 11A-E illustrate additional steps in the formation of an example tape substrate.

### DETAILED DESCRIPTION

This description relates to integrated circuits (ICs) with high-voltage (e.g., greater than approximately 200 V or more) functional isolation in a small package size (e.g., less than 3 mm by 3 mm, less than 2 mm by 2 mm, less than 1.5 mm by 1.5 mm, or smaller) and to techniques for manufacturing ICs with high-voltage functional isolation. Various examples include a first passivation layer (e.g., a polyimide or other high breakdown voltage passivation layer, a solder mask, etc.) and a second passivation layer (e.g., a polyimide or other polymer layer, a Kapton or other tape layer, etc.) formed to curtail voids, arcing, or leakage that impact isolation performance. A first set of examples are formed via a modified wafer-level fan-out (WLFO) process. A second set of examples are formed via coupling semiconductor die(s) to a tape substrate. Examples from both the first set of examples and the second set of examples have guaranteed high voltage functional isolation performance with the smallest possible package footprint, using a single metal layer (e.g., a single redistribution layer) and assembly techniques enabling the use of polyimide or tape as the dielectric materials. Various examples provide ICs with the lowest possible cost for functional isolation products and the smallest possible package size.

A quad-flat no-leads (QFN)/land grid array (LGA) footprint provides a small package size for a high-voltage functional isolation integrated circuit. However, as the package size of integrated circuits (ICs) decreases (e.g., to various sizes smaller than 3 mm by 3 mm, such as less than 2 mm by 2 mm or less than 1.5 mm by 1.5 mm, for example, 1.25 mm by 1.4 mm, or smaller), high-voltage (e.g., at least 200 V, or greater) functional isolation becomes increasingly difficult to achieve.

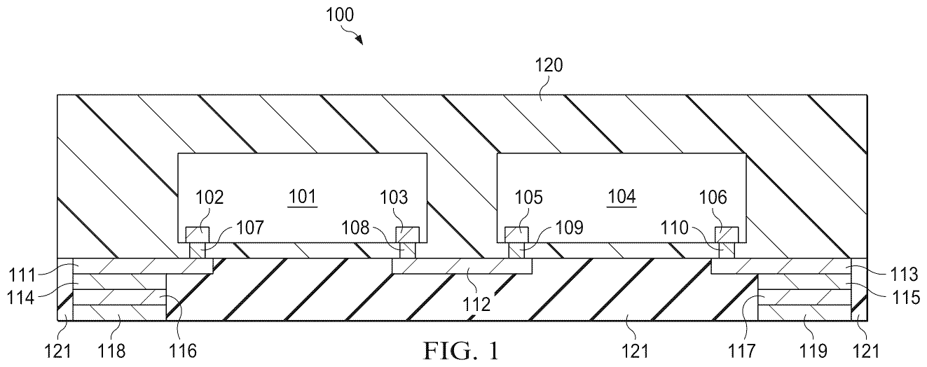

FIG. 1 illustrates a cross-sectional view of a first example integrated circuit (IC) 100 (e.g., a packaged IC). The example IC 100 includes a first semiconductor die 101 having conductive pads 102 and 103 and a second semiconductor die 104 having conductive pads 105 and 106. The conductive pad 102 is coupled to a first end of a conductive bump (e.g., or pillar) 107, the conductive pad 103 is coupled to a first end of a conductive bump 108, the conductive pad 105 is coupled to a first end of a conductive bump 109, and the conductive pad 106 is coupled to a first end of a conductive bump 110. A second end of the conductive bump 107 is coupled to a first portion 111 of a redistribution layer, second ends of the conductive bumps 108 and 109 are coupled to a second portion 112 of the redistribution layer, and a second end of the conductive bump 110 is coupled to a third portion 113 of the redistribution layer. The first portion 111 of the redistribution layer is coupled to a conductive via 114 and the third portion 113 of the redistribution layer is coupled to a conductive via 115. The conductive via 114 is coupled to a first layer 116 of a first lead and the conductive via 115 is coupled to a first layer 117 of a second lead. The first layer 116 of the first lead is coupled to a second layer 118 of the first lead and the first layer 117 of the second lead is coupled to a second layer 119 of the second lead. The number of semiconductor dies, the connection of the semiconductor dies to the redistribution layer, the layout of the redistribution layer, and the leads can vary between examples, with the IC 100 as one such example.

The semiconductor dies 101 and 104 and the conductive bumps 107, 108, 109, and 110 are encapsulated in a package encapsulation 120 (e.g., a mold compound, such as polyamide or other passivation material). The redistribution layer (e.g., including the first portion 111, the second portion 112, and the third portion 113,), the conductive vias 114 and 115, and the first lead (e.g., including the first layer 116 and the second layer 118) and the second lead (e.g., including the first layer 117 and the second layer 119) are within in a mold compound 121, with the exception of exposed surfaces of the second layer 118 and the second layer 119 for electrical connections.

The materials used in the first example IC 100 vary between examples, with one example including copper (e.g., for the conductive bumps 107, 108, 109, and 110; the first portion 111, the second portion 112, and the third portion 113 of the redistribution layer; and the conductive via 114 and the conductive via 115), nickel (e.g., for the first layer 116 of the first lead and the first layer 117 of the second lead), and gold (e.g., for the second layer 118 of the first lead and the second layer 119 of the second lead) for conductive portions.

In contrast to the circuits and methods described herein, some existing approaches (e.g., a one-layer routable leadframe (RLF), a multi-layer RLF or an embedded trace substrate (ETS)) have the potential to result in voids in the mold compound and/or have increased manufacturing complexity and cost. Voids between the metal layers reduce the breakdown voltage and cause arcing. As a result, voids significantly impact the isolation rating and can degrade the isolation rating and potentially pose a field reliability risk. Variations in the pre-molded RLF also make it difficult to guarantee isolation ratings. Additionally, exposed metal on the top layer also results in a risk of any contaminants causing arcing or leakage and impacting isolation performance.

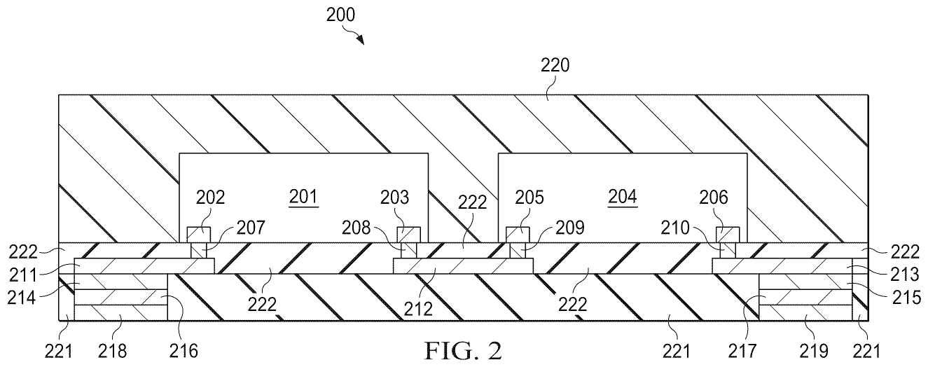

Alternatively, various examples achieve high-voltage functional isolation, in a minimal package size with reduced manufacturing complexity and cost compared to other solutions. FIG. 2 illustrates a cross-sectional view of a second example IC 200. The example IC 200 can be formed via multiple techniques to provide high-voltage functional isolation, such as via a modified WLFO process or with a tape substrate. The example IC 200 has some similarities to the example IC 100 but includes multiple passivation layers instead of a single compression molded layer of mold compound, curtailing the risk of voids as well as the risk of leakage or arcing from exposed metal.

The example IC 200 includes a first semiconductor die 201 having conductive pads 202 and 203 and a second semiconductor die 204 having conductive pads 205 and 206. The conductive pad 202 is coupled to a first end of a conductive bump (e.g., or pillar) 207, the conductive pad 203 is coupled to a first end of a conductive bump 208, the conductive pad 205 is coupled to a first end of a conductive bump 209, and the conductive pad 206 is coupled to a first end of a conductive bump 210. A second end of the conductive bump 207 is coupled to a first portion 211 of a redistribution layer, second ends of the conductive bumps 208 and 209 are coupled to a second portion 212 of the redistribution layer, and a second end of the conductive bump 210 is coupled to a third portion 213 of the redistribution layer. The first portion 211 of the redistribution layer is coupled to a conductive via 214 and the third portion 213 of the redistribution layer is coupled to a conductive via 215. The conductive via 214 is coupled to a first layer 216 of a first lead and the conductive via 215 is coupled to a first layer 217 of a second lead. The first layer 216 of the first lead is coupled to a second layer 218 of the first lead and the first layer 217 of the second lead is coupled to a second layer 219 of the second lead. The number of semiconductor dies, the connection of the semiconductor dies to the redistribution layer, the layout of the redistribution layer, and the leads can vary between examples, with the IC 200 as one such example.

The semiconductor dies 201 and 204 are encapsulated in a package encapsulation 220 (e.g., a layer of mold compound, such as polyamide or other passivation material). A first passivation layer is around at least a portion of the conductive bumps 207, 208, 209, and 210. In some examples, the conductive bumps 207, 208, 209, and 210 are completely within the first passivation layer, while in other examples a portion of the conductive bumps 207, 208, 209, and 210 is within the first passivation layer and another portion of the conductive bumps 207, 208, 209, and 210 is encapsulated within the package encapsulation 220. The first passivation layer and/or a second passivation layer is around the redistribution layer (e.g., including the first portion 211, the second portion 212, and the third portion 213). In some examples, the first passivation layer is around the redistribution layer and a surface of the redistribution layer opposite of the conductive bumps 207, 208, 209, and 210 is adjacent to the second passivation layer. In other examples, the second passivation layer is around the redistribution layer and a surface of the redistribution layer adjacent to the conductive bumps 207, 208, 209, and 210 is adjacent to the first passivation layer. The second passivation layer is also around the conductive vias 214 and 215, the first lead (e.g., including the first layer 216 and the second layer 218), and the second lead (e.g., including the first layer 217 and the second layer 219), with the exception of exposed surfaces of the second layer 218 and the second layer 219 for electrical connections. The region 221 (around the conductive vias 214 and 215 and the first and second leads) is formed from the second passivation layer (e.g., a mold compound, such as polyamide or other passivation material). The region 222 (around the redistribution layer and the conductive bumps 207, 208, 209, and 210) is formed in part from the first passivation layer, and in part from the second passivation layer and/or the package encapsulation. In some examples, the region 222 is formed from the first passivation layer (e.g., around the conductive bumps 207, 208, 209, and 210) and the second passivation layer (e.g., around the redistribution layer). In other examples, the region 222 is formed from the first passivation layer (e.g., around the redistribution layer and a portion of the conductive bumps 207, 208, 209, and 210) and the package encapsulation (e.g., around another portion of the conductive bumps 207, 208, 209, and 210).

The materials used in the second example IC 200 can vary between examples, with one example including copper (e.g., for the conductive bumps 207, 208, 209, and 210; the first portion 211, the second portion 212, and the third portion 213 of the redistribution layer; and the conductive via 214 and the conductive via 215), nickel (e.g., for the first layer 216 of the first lead and the first layer 217 of the second lead), and gold (e.g., for the second layer 218 of the first lead and the second layer 219 of the second lead) for conductive portions. In some examples (e.g., WLFO examples), the first passivation layer and the second passivation layer are layers of polyimide or another passivation material with high breakdown voltage (e.g., greater than 30 V/μm, greater than 300 V/μm, or more). In other examples (e.g., tape substrate examples), the first passivation layer is a solder mask and the second passivation layer is a tape substrate (e.g., a polyimide tape, Kapton tape, etc.).

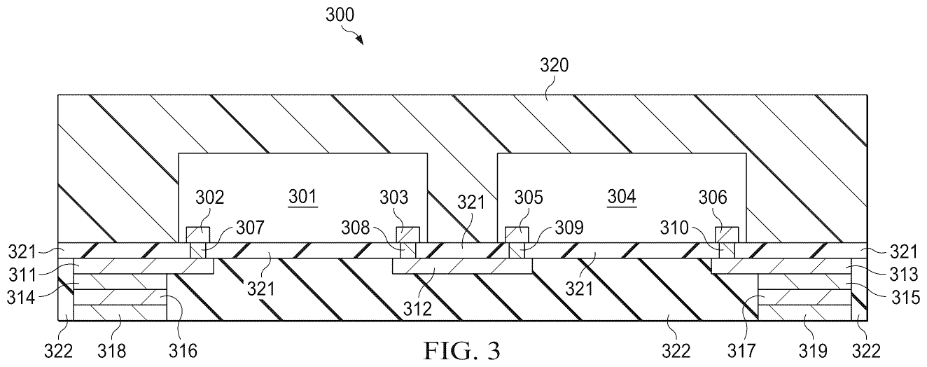

FIG. 3 illustrates a cross-sectional view of a third example IC 300. The example IC 300 is formed via a modified WLFO process for high-voltage isolation with a LGA footprint. The example IC 300 includes multiple passivation layers (e.g., polyimide or another passivation material with high breakdown voltage) instead of a single compression molded layer of mold compound, curtailing the risk of voids as well as the risk of leakage or arcing from exposed metal. Additionally, the example IC 300 is able to be produced in a minimal package size with reduced manufacturing complexity and cost compared to existing multi-layer RLF or multi-layer laminate substrate ICs.

The example IC 300 includes a first semiconductor die 301 having conductive pads 302 and 303 and a second semiconductor die 304 having conductive pads 305 and 306. The conductive pad 302 is coupled to a first end of a conductive bump (e.g., or pillar) 307, the conductive pad 303 is coupled to a first end of a conductive bump 308, the conductive pad 305 is coupled to a first end of a conductive bump 309, and the conductive pad 306 is coupled to a first end of a conductive bump 310. A second end of the conductive bump 307 is coupled to a first portion 311 of a redistribution layer, second ends of the conductive bumps 308 and 309 are coupled to a second portion 312 of the redistribution layer, and a second end of the conductive bump 310 is coupled to a third portion 313 of the redistribution layer. The first portion 311 of the redistribution layer is coupled to a conductive via 314 and the third portion 313 of the redistribution layer is coupled to a conductive via 315. The conductive via 314 is coupled to a first layer 316 of a first lead and the conductive via 315 is coupled to a first layer 317 of a second lead. The first layer 316 of the first lead is coupled to a second layer 318 of the first lead and the first layer 317 of the second lead is coupled to a second layer 319 of the second lead. As with IC 100 and IC 200, the number of semiconductor dies, the connection of the semiconductor dies to the redistribution layer, the layout of the redistribution layer, and the leads can vary between examples, with the IC 300 as one such example.

The semiconductor dies 301 and 304 are encapsulated in a package encapsulation 320. A first passivation layer 321 is around the conductive bumps 307, 308, 309, and 310 and a surface of the redistribution layer (e.g., including the first portion 311, the second portion 312, and the third portion 313) adjacent to the conductive bumps 307, 308, 309, and 310 is adjacent to the first passivation layer. A second passivation layer 322 is around the redistribution layer, the conductive vias 314 and 315, the first lead (e.g., including the first layer 316 and the second layer 318), and the second lead (e.g., including the first layer 317 and the second layer 319), with the exception of exposed surfaces of the second layer 318 and the second layer 319 for electrical connections.

The materials used in the third example IC 300 vary between examples, with one example including copper (e.g., copper plating for the conductive bumps 307, 308, 309, and 310; the first portion 311, the second portion 312, and the third portion 313 of the redistribution layer; and the conductive via 314 and the conductive via 315), nickel (e.g., nickel plating for the first layer 316 of the first lead and the first layer 317 of the second lead), and gold (e.g., gold plating for the second layer 318 of the first lead and the second layer 319 of the second lead) for conductive portions. In various examples, the first passivation layer 321 and the second passivation layer 322 are layers of polyimide or another passivation material with high breakdown voltage and can be applied at the wafer level.

In one example, the first and second passivation layers 321 and 322 are about 25 μm thick, with about 5 μm of the first passivation layer 321 between the semiconductor dies 301 and 304 and the redistribution layer. The redistribution layer and the conductive vias 314 and 315 are each about 20 μm thick. The first layer 316 of the first lead and the first layer 317 of the second lead are each about 5 μm thick, and the second layer 318 of the first lead and the second layer 319 of the second lead are each less than 1 μm thick. In other examples, the dimensions can vary based on multiple factors, such as the package size, materials and their associated properties (e.g., polyimide film has a breakdown voltage of greater than 300 V/μm), and target level of functional isolation.

The example IC 300 curtails the risk of voids impacting high-voltage isolation performance without including a RLF or other multi-layer substrate. By modifying the WLFO process, for example, by omitting under bump metallization (UBM) and ball attach and plating nickel and gold for the leads, the IC 300 can have an LGA footprint and match the same form factor as a QFN package. In various examples, the first passivation layer 321 and/or the second passivation layer 322 are modified to further increase isolation performance, improve creepage/clearance, and/or reduce package size further. The example IC 300 has a reduced likelihood of any leakage or arcing as all the conductive bumps 307, 308, 309, and 310 are completely covered by the first passivation layer 321 (e.g., made of polyimide or similar material). Polyimide film (e.g., and similar materials) does not have any voids, guaranteeing a void-free construction and no risk of arcing. The conductive bumps 307, 308, 309, and 310, the redistribution layer (including portions 307, 308, and 309) and conductive vias 314 and 315 can be formed directly on the bond pads 302, 303, 304, and 305, curtailing the risk of exposed metal or contamination causing arcing. Polyimide or similar materials (e.g., used for the first passivation layer 321 and the second passivation layer 322) has a much higher breakdown voltage (e.g., greater than 30 V/μm) than mold compound (e.g., around 3 V/μm), allowing for the example IC 300 to achieve high-voltage (e.g., around 200 V or more) functional isolation. Various examples can enable additional package size reduction from the example dimensions provided for the IC 300, as creepage and/or clearance for isolation is improved via using polyimide or similar materials as the dielectric (e.g., in the first passivation layer 321 and/or the second passivation layer 322).

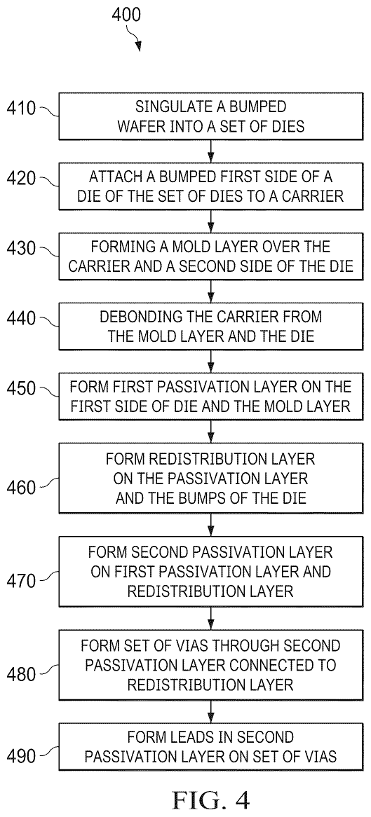

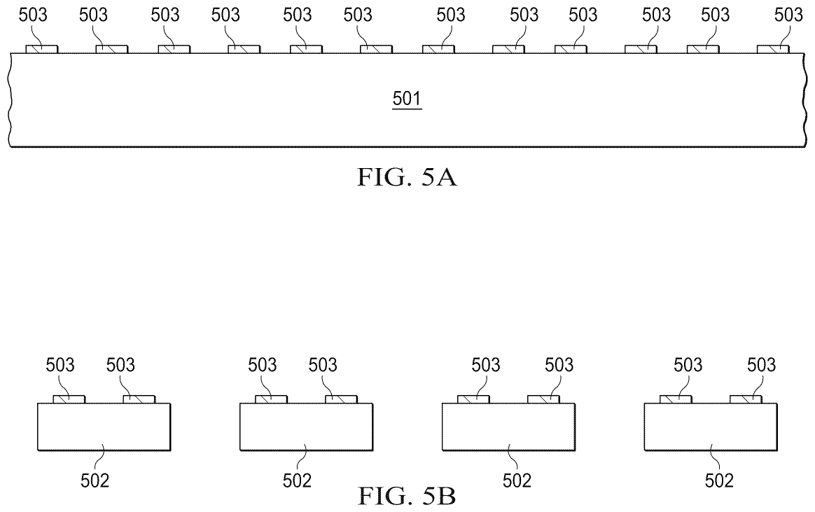

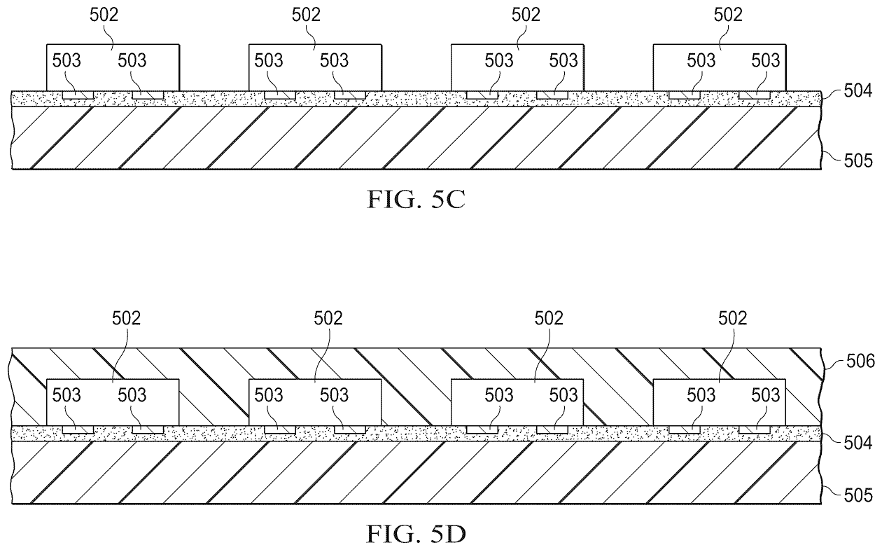

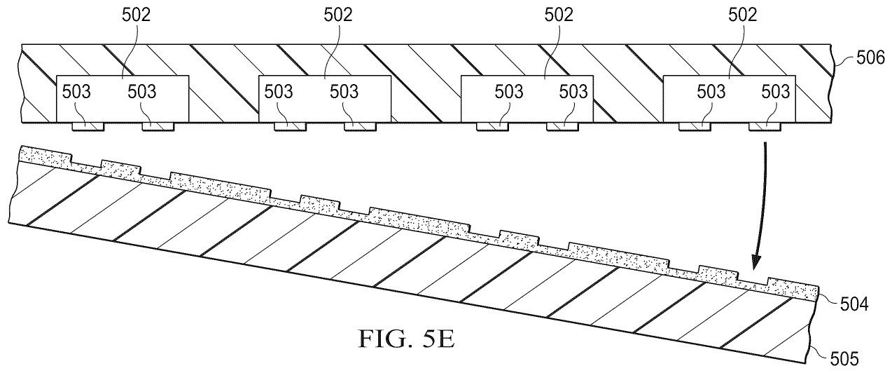

FIG. 4 illustrates a first example method 400 for formation of an IC via a modified WLFO technique, such as the IC 300 of FIG. 3 or some examples of the IC 200 of FIG. 2. FIGS. 5A-E and 6A-E show views of steps in formation (e.g., via the method 400) of an example IC via a modified WLFO technique, such as the IC 300 of FIG. 3 or some examples of the IC 200 of FIG. 2.

While, for purposes of simplicity of explanation, the example method 400 of FIG. 4 is shown and described as executing serially, it is to be understood and appreciated that the example method of FIG. 4 is not limited by the illustrated order, as some actions could in other examples occur in different orders, multiple times and/or concurrently from that shown and described herein. Moreover, it is not necessary that all described actions be performed to implement the method 400.

At 410, the method 400 includes singulating a bumped wafer into a set of semiconductor dies (e.g., the semiconductor dies 201 and 204, the semiconductor dies 301 and 304, etc.). FIG. 5A shows an example fabricated wafer 501, prior to singulation into a set of semiconductor dies 502 (e.g., as shown in FIG. 5B). The wafer 501 has a set of conductive bumps 503 attached to conductive pads at locations that depend on the semiconductor dies 502. FIG. 5B shows the prepared set of semiconductor dies 502 after backgrinding and sawing of the wafer 501 into set semiconductor dies 502.

At 420, the method 400 includes attaching a first side of a die (e.g., the semiconductor die 201, 204, 301, or 304) of the set of dies (e.g., a side coupled to the conductive bumps) to a carrier. FIG. 5C shows the set of semiconductor dies 502 (shown inverted relative to FIG. 5B) attached to a temporary bonding layer 504 that bonds the set of semiconductor dies 502 to a carrier 505.

At 430, the method 400 includes forming a mold layer (e.g., the package encapsulation 220, the package encapsulation 320, etc.) over the carrier and a second side of the die (e.g., a side opposite the side coupled to the conductive bumps). FIG. 5D shows a mold layer 506 formed over the first side of the semiconductor dies 502 and the carrier 505 via the temporary bonding layer 504.

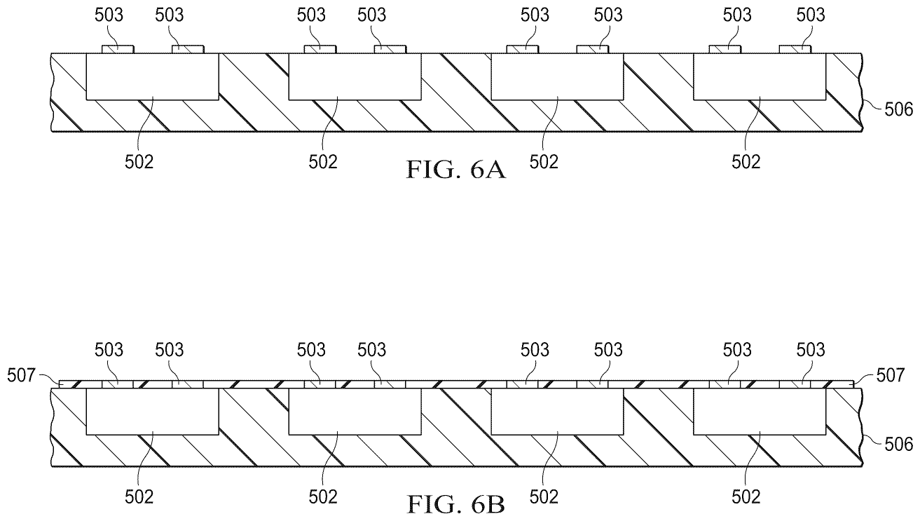

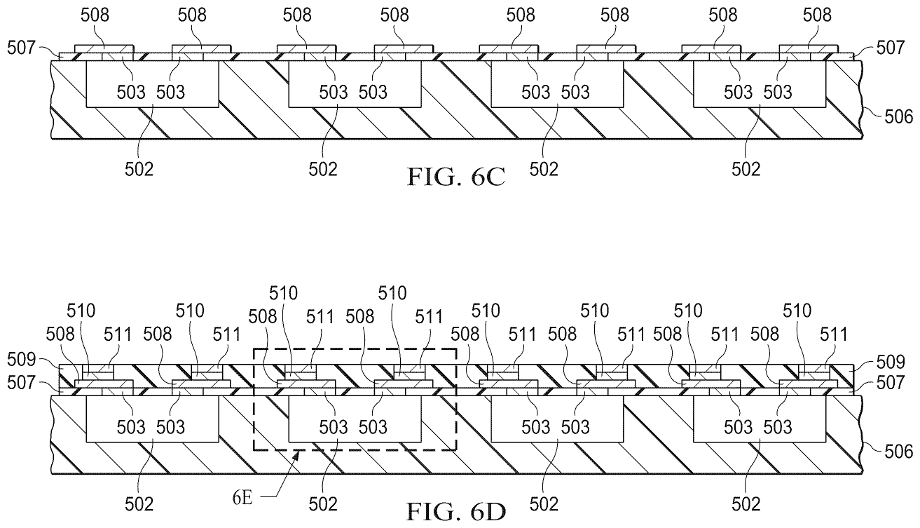

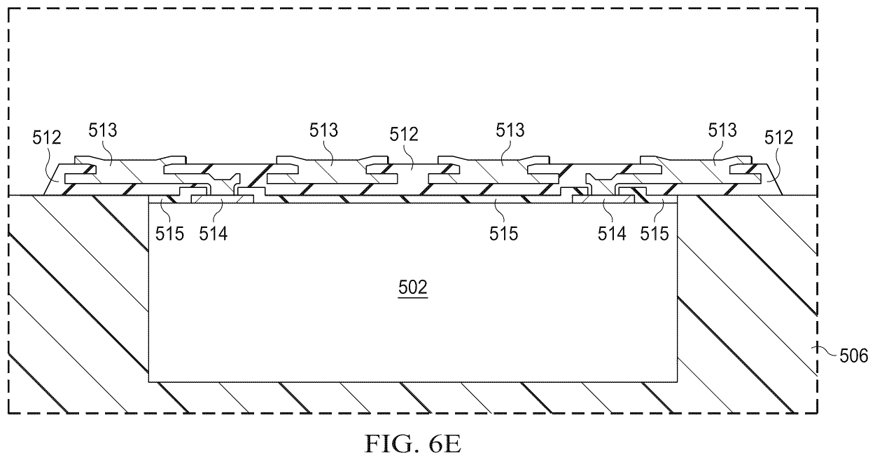

At 440, the method 400 includes debonding the carrier from the mold layer and the semiconductor die. FIG. 5E shows the carrier 505 and temporary bonding layer 504 being removed from the semiconductor dies 502, the conductive bumps 503, and mold layer 506. FIG. 6A shows the semiconductor dies 502, the conductive bumps 503, and mold layer 506 (shown inverted relative to FIG. 5E) after removal of the carrier 505 and the temporary bonding layer 504.

At 450, the method 400 includes forming a first passivation layer (e.g., the first passivation layer 221, the first passivation layer 321) on the first side of the semiconductor die and a given side of the mold layer. FIG. 6B shows a first passivation layer 507 (e.g., the first passivation layer 221, the first passivation layer 321) formed on the first side of the semiconductor dies 502 and a given side of the mold layer 506, and around the conductive bumps 503.

At 460, the method 400 includes forming a redistribution layer (e.g., including the portions 211, 212, and/or 213, including the portions 311, 312, and/or 313, etc.) on a given side of the first passivation layer and coupled to a second end of the conductive bump (e.g., opposite an end coupled to the semiconductor die). FIG. 6C shows a redistribution layer 508 (e.g., including the portions 211, 212, and/or 213, including the portions 311, 312, and/or 313) coupled to the conductive bumps 503 and a given side of the first passivation layer 507.

At 470, the method 400 includes forming a second passivation layer (e.g., the first passivation layer 221, the first passivation layer 321) on the given side of the first passivation layer and a given side of the redistribution layer. FIG. 6D shows a second passivation layer 509 (e.g., the first passivation layer 221, the first passivation layer 321) formed on the given side of the first passivation layer 507 and a given side of the redistribution layer 508.

At 480, the method 400 includes forming a set of vias (e.g., the conductive vias 214, 215, 314, and/or 315) through the second passivation layer. Vias of the set of vias have first ends (e.g., for coupling to leads) and second ends coupled to the given side of the redistribution layer. FIG. 6D also shows a set of vias 510 through the second passivation layer 509, coupled to the redistribution layer 508 and to a set of leads 511.

At 490, the method 400 includes forming a set of leads (e.g., the first leads including first and second layers 216 and 218, or the first leads including first and second layers 316 and 318) in the second passivation layer. Leads of the set of leads are coupled to the first ends of vias of the set of vias. FIG. 6D additionally shows a set of leads 511 coupled to the first ends of the set of vias 510. FIG. 6E is a close-up view of the region of FIG. 6D within the dashed rectangle. FIG. 6E shows one example semiconductor die 502 within a portion of the mold layer 506. The passivation layers 512 are around the leads 513, connected to the pads 514 of the semiconductor die through an insulating layer 515.

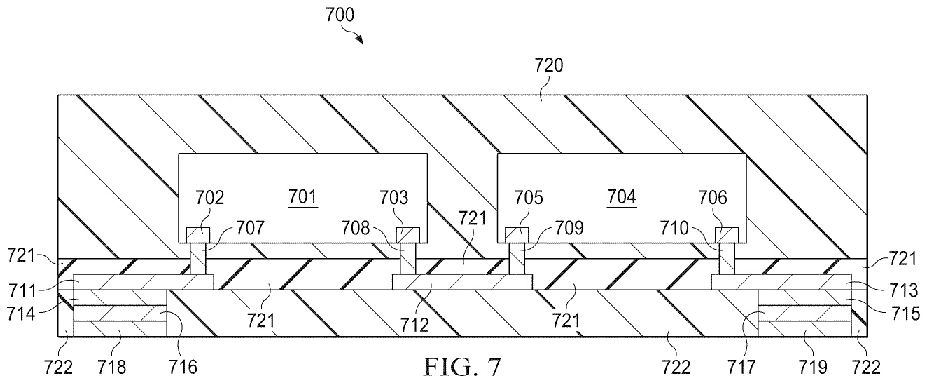

FIG. 7 illustrates a cross-sectional view of a fourth example IC 700. The example IC 700 is formed via attaching semiconductor dies to a tape substrate. The example IC 700 includes multiple passivation layers (e.g., a tape substrate and a solder mask, etc.) instead of a single compression molded layer of mold compound, curtailing the risk of voids as well as the risk of leakage or arcing from exposed metal, providing high voltage isolation with an LGA footprint. Additionally, the example IC 700 is able to be produced in a minimal package size with reduced manufacturing complexity and cost compared to multi-layer RLF or multi-layer laminate substrate ICs.

The example IC 700 includes a first semiconductor die 701 having conductive pads 702 and 703 and a second semiconductor die 704 having conductive pads 705 and 706. The conductive pad 702 is coupled to a first end of a conductive bump (e.g., or pillar) 707, the conductive pad 703 is coupled to a first end of a conductive bump 708, the conductive pad 705 is coupled to a first end of a conductive bump 709, and the conductive pad 706 is coupled to a first end of a conductive bump 710. The conductive bumps 707, 708, 709, and 710 couple the first and second semiconductor dies 701 and 704 to a tape substrate.

A second end of the conductive bump 707 is coupled to a first portion 711 of a redistribution layer, second ends of the conductive bumps 708 and 709 are coupled to a second portion 712 of the redistribution layer, and a second end of the conductive bump 710 is coupled to a third portion 713 of the redistribution layer. The first portion 711 of the redistribution layer is coupled to a conductive via 714 and the third portion 713 of the redistribution layer is coupled to a conductive via 715. The conductive via 714 is coupled to a first layer 716 of a first lead and the conductive via 715 is coupled to a first layer 717 of a second lead. The first layer 716 of the first lead is coupled to a second layer 718 of the first lead and the first layer 717 of the second lead is coupled to a second layer 719 of the second lead. A first passivation layer 721 (e.g., a solder mask layer of a polymer or other insulating material) is around a portion of the conductive bumps 707, 708, 709, and 710 and around the redistribution layer (e.g., including the first portion 711, the second portion 712, and the third portion 713). A second passivation layer 722 (e.g., a Kapton or other tape layer) is adjacent to a surface of the redistribution layer and is around the conductive vias 714 and 715, the first lead (e.g., including the first layer 716 and the second layer 718), and the second lead (e.g., including the first layer 717 and the second layer 719), with the exception of exposed surfaces of the second layer 718 and the second layer 719 for electrical connections. The first passivation layer 721 (e.g., including holes for coupling the redistribution layer to the conductive bumps 707, 708, 709, and 710), the second passivation layer 722, the redistribution layer, the conductive vias 714 and 715, and the first lead and the second lead are part of a tape substrate configured to couple with the semiconductor dies 701 and 704.

The semiconductor dies 701 and 704 and are encapsulated in a package encapsulation 720.

As with ICs 100, 200, and 300, the number of semiconductor dies, the connection of the semiconductor dies to the redistribution layer, the layout of the redistribution layer, and the leads can vary between examples, with the IC 700 as one such example.

The materials used in the fourth example IC 700 can vary between examples, with one example including copper (e.g., copper plating for the conductive bumps 707, 708, 709, and 710; the first portion 711, the second portion 712, and the third portion 713 of the redistribution layer; and the conductive via 714 and the conductive via 715), nickel (e.g., nickel plating for the first layer 716 of the first lead and the first layer 717 of the second lead), and gold (e.g., gold plating for the second layer 718 of the first lead and the second layer 719 of the second lead) for conductive portions. In various examples, the first passivation layer 721 is a polymer solder mask (e.g., with relatively high breakdown voltage such as greater than 30 V/μm, greater than 300 V/μm, or more) and the second passivation layer 722 is a tape layer (e.g., Kapton tape, a polyimide time or another tape with relatively high breakdown voltage such as greater than 30 V/μm, greater than 300 V/μm, or more).

In one example, the first and second passivation layers 721 and 722 are about 25 μm thick, with about 5 μm of the first passivation layer 721 between the semiconductor dies 701 and 704 and the redistribution layer. The redistribution layer and the conductive vias 714 and 715 are each about 20 μm thick. The first layer 716 of the first lead and the first layer 717 of the second lead are each about 5 μm thick, and the second layer 718 of the first lead and the second layer 719 of the second lead are each less than 1 μm thick. In other examples, the dimensions can vary based on multiple factors, such as the package size, materials and their associated properties (e.g., Kapton tape has a breakdown voltage of greater than 300 V/μm), and target level of functional isolation.

The example IC 700 curtails the risk of voids impacting high-voltage isolation performance, providing high-voltage functional isolation with an LGA footprint without including a RLF or multi-layer substrate. The conductive vias 714 and 715 are within holes punched in the second passivation layer 722 (e.g., a tape layer), such as by conductive (e.g., copper or another conductive material) foil attached to the second passivation layer 722 with an adhesive and then etched based on a selected design, with the first passivation layer 721 (e.g., a solder mask layer) covering any exposed metal. Unlike a tape substrate package having a ball grid array (BGA) footprint where solder balls are reflowed into holes in the tape substrate, the conductive vias 714 and 715 (e.g., made of copper) and first and second leads (e.g., made of nickel and gold) can be plated into holes in the second passivation layer 722 to enable a LGA footprint. While some examples of the IC 700 use Kapton tape as the second passivation layer 722, which provides superior dielectric properties, other examples use alternative tape materials, including tape with a higher dielectric strength, for the second passivation layer 722.

The example IC 700 has a reduced likelihood of any voids, leakage or arcing degrading performance. Tape film (e.g., Kapton tape, other polyimide tape, or similar tape, useable as the second passivation layer 722.) does not have any voids, guaranteeing the example IC 700 will be free of voids and risk of arcing. The first passivation layer 721 (e.g., a solder mask layer) covers the surface of the redistribution layer coupled to the conductive bumps 707, 708, 709, and 710, curtailing the risk of exposed metal or contamination causing arcing. Additionally, Kapton and similar tapes (e.g., used for the second passivation layer 322) have a much higher breakdown voltage (e.g., greater than 300 V/μm) than mold compound (e.g., around 3 V/μm), allowing for the example IC 700 to achieve high-voltage (e.g., around 200 V or more) functional isolation. Various examples can enable additional package size reduction from the example dimensions provided for the IC 700, as creepage and/or clearance for isolation is improved via using Kapton or similar tape as the dielectric (e.g., in the second passivation layer 322).

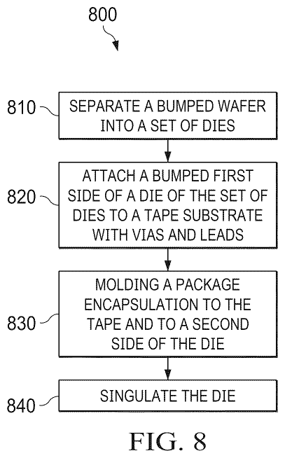

FIG. 8 illustrates a method 800 for formation of an IC via attachment to a tape substrate, such as the IC 700 of FIG. 7 or some examples of the IC 200 of FIG. 2.

While, for purposes of simplicity of explanation, the example method of FIG. 8 is shown and described as executing serially, it is to be understood and appreciated that the example method of FIG. 8 is not limited by the illustrated order, as some actions could in other examples occur in different orders, multiple times and/or concurrently from that shown and described herein. Moreover, it is not necessary that all described actions be performed to implement a method.

At 810, the method 800 includes separating a bumped wafer (e.g., a wafer that includes a set of semiconductor dies such as the semiconductor dies 201, 204, 701, and/or 704 coupled on a given side to a set of conductive bumps, e.g., the conductive bumps 207, 208, 209, 210, 707, 708, 709, and/or 710) into a set of semiconductor dies (e.g., via sawing, backgrinding, etc.).

At 820, the method 800 includes attaching the given side of a semiconductor die of the set of semiconductor dies to a tape substrate (e.g., the tape substrate of FIG. 7, including the redistribution layer portions 711, 712, and 713, the conductive vias 714 and 715, the first lead including layers 716 and 718, the second lead including layers 717 and 719, the first passivation layer 721, and the second passivation layer 722). In various examples, the tape substrate has a set of holes to couple the conductive bumps to a redistribution layer of the tape substrate. In various examples, the semiconductor die is attached along with one or more other semiconductor dies to a strip of tape substrate.

At 830, the method 800 includes molding a package encapsulation (e.g., the package encapsulation 720) to the tape substrate (e.g., to the first passivation layer 721) and to a second side of the semiconductor die opposite the given side (e.g., coupled to the conductive bumps) of the semiconductor die.

At 840, the method includes singulating the semiconductor die, such as by marking and singulating the semiconductor die and the one or more other semiconductor dies attached to the strip of the tape substrate. Once singulated, electrical testing can be performed on the resulting IC.

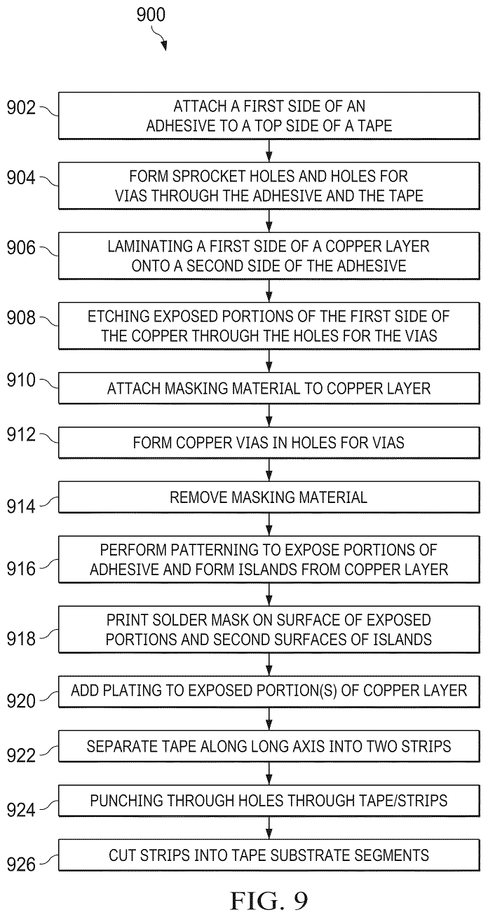

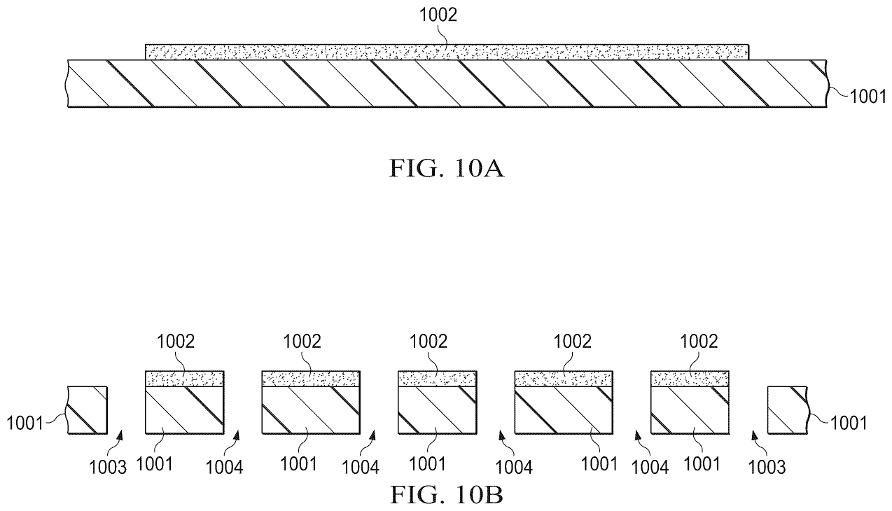

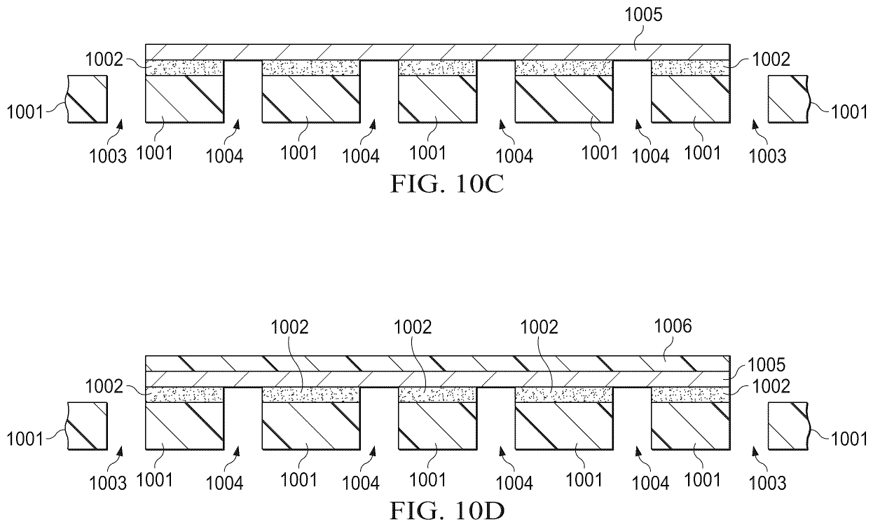

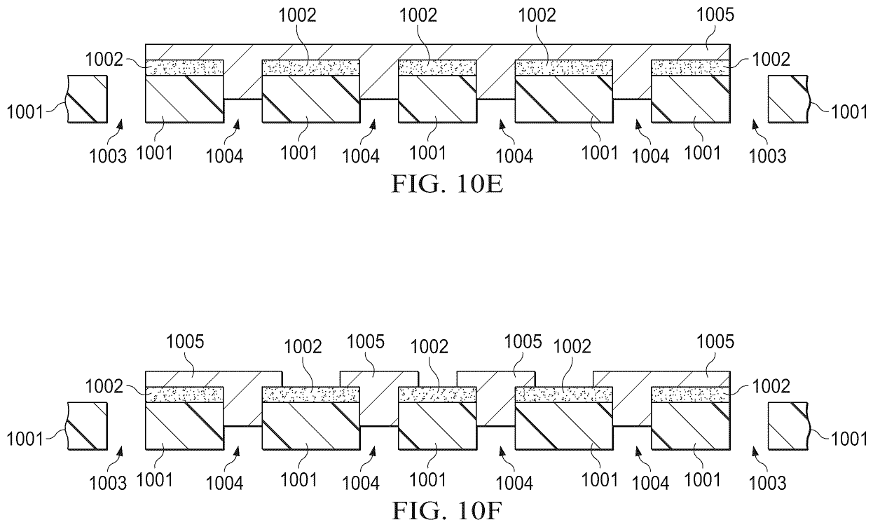

FIG. 9 illustrates a method 900 for formation of a tape substrate, such as in the IC 700 of FIG. 7 or some examples of the IC 200 of FIG. 2. FIGS. 10A-F and 11A-E show views of steps in formation (e.g., via the method 400) of an example tape substrate, such as in the IC 700 of FIG. 7 or some examples of the IC 200 of FIG. 2.

While, for purposes of simplicity of explanation, the example method 900 of FIG. 9 is shown and described as executing serially, it is to be understood and appreciated that the example method 900 of FIG. 9 is not limited by the illustrated order, as some actions could in other examples occur in different orders, multiple times and/or concurrently from that shown and described herein. Moreover, it is not necessary that all described actions be performed to implement the method 900.

At 902, the method 900 includes attaching a first side of an adhesive to a top side of a tape layer (e.g., a tape layer that includes a second passivation layer 222, a second passivation layer 722). FIG. 10A shows a tape layer 1001 (e.g., that includes a second passivation layer 222, a second passivation layer 722) coupled to an adhesive layer 1002.

At 904, the method 900 includes forming sprocket holes (e.g., for positioning the tape layer 1001, such as for formation of an IC 200, an IC 700) and holes for vias (e.g., the conductive vias 214, 215, 714, and/or 715) through the adhesive 1002 and the tape layer 1001. FIG. 10B shows the tape layer 1001 (e.g., for positioning the tape layer 1001, such as for formation of an IC 200, an IC 700) and the adhesive layer 1002 with sprocket holes 1003 and holes 1004 for vias (e.g., the conductive vias 214, 215, 714, and/or 715) punched through the tape layer 1001 and the adhesive layer 1002.

At 906, the method 900 includes laminating a first side of a copper layer onto a second side of the adhesive layer (e.g., a side opposite the tape layer) and curing. FIG. 10C shows a copper layer 1005 (e.g., from which a redistribution layer is formed, for example, including first portion 211, second portion 212, third portion 213, first portion 711, second portion 712, and/or third portion 713).

At 908, the method 900 includes etching exposed portions of the first side of the copper through the holes for the vias. FIG. 10C shows the holes 1004 for the vias through which exposed portions of the copper layer 1005 are etched.

At 910, the method 900 includes attaching a masking material to the copper layer. FIG. 10D shows a masking material 1006 attached to the copper layer 1005 (not shown in FIG. 10D but shown in FIG. 10C).

At 912, the method 900 includes forming copper vias in the holes for vias formed at 904, building on the copper laminated at 906.

At 914, the method 900 includes removing the masking material attached at 910. FIG. 10E shows the copper layer 1005 (e.g., from which a redistribution layer is formed, for example, including first portion 211, second portion 212, third portion 213, first portion 711, second portion 712, and/or third portion 713, and conductive vias are formed, for example, conductive vias 214, 215, 714, and/or 715) extending into the holes for vias 1004, with the masking material 1006 (not shown in FIG. 10E but shown in FIG. 10D) removed.

At 916, the method 900 includes performing patterning (e.g., resist coating, exposure, development, etching, resist stripping, etc.) to expose portions of the adhesive and form islands from the copper layer, for example, based on semiconductor die(s) (e.g., the semiconductor dies 201, 204, 701, and/or 704) the copper layer is configured to be coupled to via conductive bumps (e.g., the conductive bumps 207, 208, 209, 210, 707, 708, 709, and/or 710). FIG. 10F shows islands formed from the copper layer 1005 based on patterning, for example, based on semiconductor die(s) (e.g., the semiconductor dies 201, 204, 701, and/or 704) the copper layer 1005 is configured to be coupled to via conductive bumps (e.g., the conductive bumps 207, 208, 209, 210, 707, 708, 709, and/or 710).

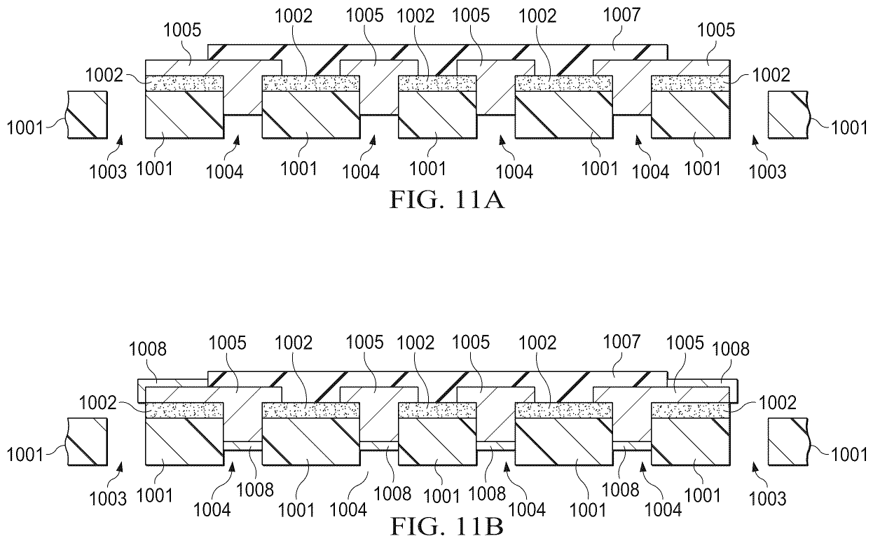

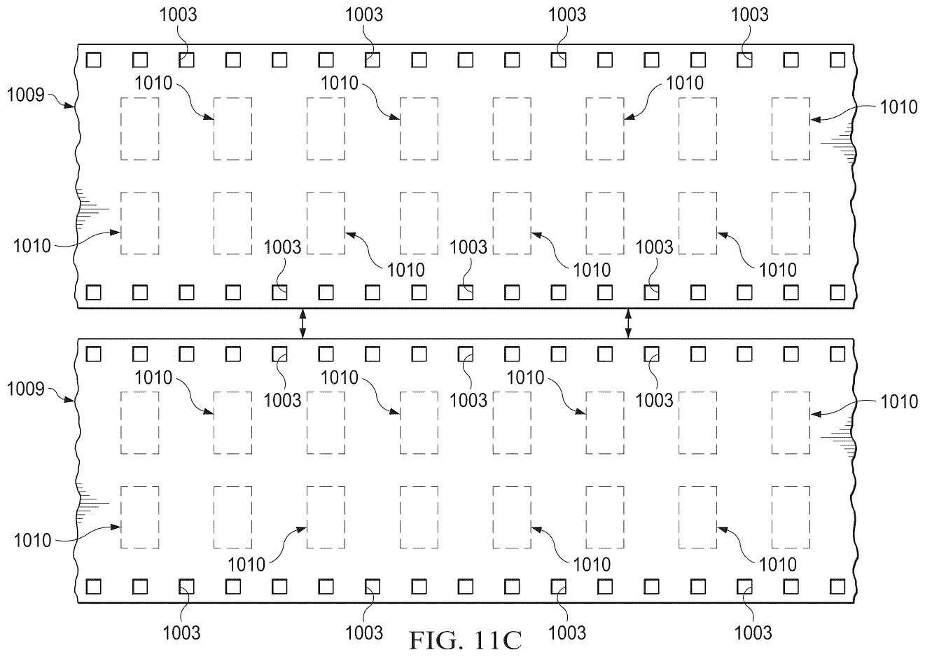

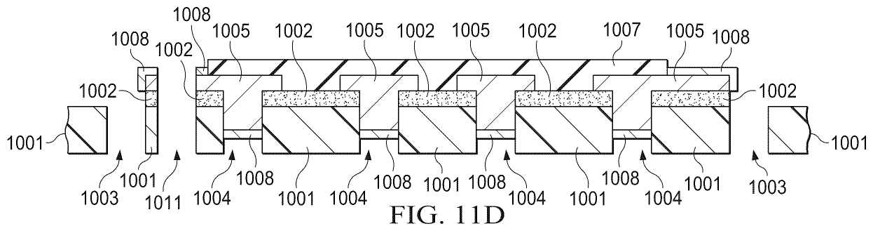

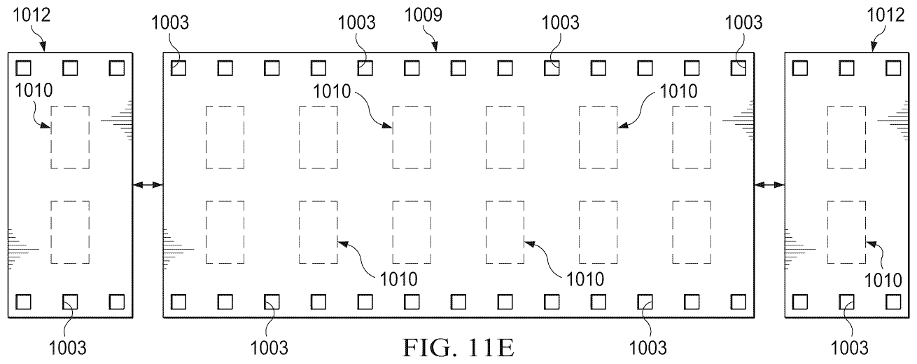

At 918, the method 900 includes printing a solder mask (e.g., including a first passivation layer 221, a first passivation layer 721, etc.) on a surface of the exposed portions of the adhesive layer and on portions (e.g., portions other than locations for coupling to conductive bumps) of the second surfaces of the islands of the copper layer (e.g., a surface opposite the surface of the copper layer coupled to the adhesive). FIG. 11A shows a solder mask 1007 (e.g., including a first passivation layer 221, a first passivation layer 721, etc.), printed over portions (e.g., portions other than locations for coupling to conductive bumps) of the islands of the copper layer 1005 and an exposed surface of the adhesive layer 1002.

At 920, the method 900 includes adding plating to exposed portions of the copper layer (e.g., exposed portions of the islands and exposed portions of the copper layer in the holes for the vias). In various examples, the plating involves adding nickel plating to the exposed portions of the copper layer and adding gold plating to the nickel plating. FIG. 11B shows plating (e.g., including nickel and gold layers) added to exposed portions of the copper layer 1005.

At 922, the method 900 includes separating the tape substrate along its long axis into multiple (e.g., two or more) strips of tape substrate. FIG. 11C shows a top view of two strips 1009 of tape substrate separated from one another, along with the sprocket holes 1003 and locations 1010 for coupling the tape substrate to semiconductor die(s) (e.g., the semiconductor die(s) 201, 204, 701, and/or 704).

At 924, the method 900 includes punching through holes through the tape substrate (e.g., when step 924 is performed before step 922) or through strips of tape substrate (e.g., when step 922 is performed before step 924). FIG. 11D shows an example through hole 1011 punched through the substrate (e.g., through the plating 1008, the copper layer 1005, the adhesive layer 1002, and the tape layer 1001).

At 926, the method 900 includes cutting the tape layer strips into tape layer segments (e.g., that include a tape layer useable as a second passivation layer 222 or as a second passivation layer 722) for fabrication of ICs via coupling to semiconductor dies, encapsulation, and singulation (e.g., via method 800). FIG. 11E shows a top view of a tape layer strip 1009 separated from two example tape layer segments 1012 (e.g., for fabrication of ICs via coupling to semiconductor dies, encapsulation, and singulation, for example via method 800).

In this description, unless otherwise stated, “about,” “approximately” or “substantially” preceding a parameter means being within +/−10 percent of that parameter. Modifications are possible in the described embodiments, and other embodiments are possible, within the scope of the claims.

In this description, the term “couple” can cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In this description, a device that is “configured to” perform a task or function can be configured (e.g., programmed and/or hardwired) at a time of manufacturing by a manufacturer to perform the function and/or can be configurable (or reconfigurable) by a user after manufacturing to perform the function and/or other additional or alternative functions. The configuring can be through firmware and/or software programming of the device, through a construction and/or layout of hardware components and interconnections of the device, or a combination thereof. Furthermore, a circuit or device that is described herein as including certain components can instead be configured to couple to those components to form the described circuitry or device. For example, a structure described herein as including one or more semiconductor elements (such as transistors), one or more passive elements (such as resistors, capacitors, and/or inductors), and/or one or more sources (such as voltage and/or current sources) can instead include only the semiconductor elements within a single physical device (e.g., a semiconductor die and/or integrated circuit (IC) package) and can be configured to couple to at least some of the passive elements and/or the sources to form the described structure, either at a time of manufacture or after a time of manufacture, such as by an end-user and/or a third-party.

The phrase “based on” means “based at least in part on”. Therefore, if X is based on Y, X can be a function of Y and any number of other factors.

Modifications are possible in the described embodiments, and other embodiments are possible, within the scope of the claims.

What is claimed is:

1. An integrated circuit, comprising:
a semiconductor die including a set of conductive pads on a given side of the die;
a set of conductive bumps, wherein a conductive bump of the set of conductive bumps has a first end and a second end, and the first end of the conductive bump is coupled to a respective pad of the set of conductive pads;
a first passivation layer around the set of conductive bumps;
a redistribution layer coupled to the second end of the conductive bump;
a lead;
a second passivation layer around the lead; and
a conductive via coupled, in the second passivation layer, between the redistribution layer and the lead.

2. The integrated circuit of claim 1, wherein the first passivation layer is a polyimide layer.

3. The integrated circuit of claim 1, wherein the second passivation layer is a polyimide layer.

4. The integrated circuit of claim 1, wherein the first passivation layer is a solder mask.

5. The integrated circuit of claim 1, wherein the second passivation layer is a tape substrate.

6. The integrated circuit of claim 1, wherein a thickness of the first passivation layer is between 90% of a thickness of the second passivation layer and 110% of the thickness of the second passivation layer.

7. The integrated circuit of claim 1, wherein the first passivation layer has a first breakdown voltage greater than 30 V/μm and the second passivation layer has a second breakdown voltage greater than 30 V/μm.

8. The integrated circuit of claim 1, wherein the redistribution layer and the via comprise copper.

9. The integrated circuit of claim 1, wherein the lead comprises a nickel layer and a gold layer.

10. A method, comprising:
attaching a carrier to a set of conductive bumps and to a first side of a semiconductor die that includes a set of conductive pads on the first side of the die, wherein a conductive bump of the set of conductive bumps has a first end and a second end, and the first end of the conductive bump is coupled to a respective pad of the set of conductive pads;
forming a mold layer over the carrier and a second side of the semiconductor die;
removing the carrier from the mold layer and the semiconductor die;
forming a first passivation layer on the first side of the semiconductor die and a given side of the mold layer;
forming a redistribution layer on a given side of the first passivation layer and coupled to the second end of the conductive bump;
forming a second passivation layer on the given side of the first passivation layer and a given side of the redistribution layer;
forming a set of vias through the second passivation layer, wherein a via of the set of vias has a first end and a second end coupled to the given side of the redistribution layer; and
forming a set of leads in the second passivation layer, wherein a lead of the set of leads is coupled to the first end of the via.

11. The method of claim 10, wherein the first passivation layer is a polyimide layer.

12. The method of claim 10, wherein the second passivation layer is a polyimide layer.

13. The method of claim 10, wherein a thickness of the first passivation layer is between 90% of a thickness of the second passivation layer and 110% of the thickness of the second passivation layer.

14. The method of claim 10, wherein the first passivation layer has a first breakdown voltage greater than 30 V/μm and the second passivation layer has a second breakdown voltage greater than 30 V/μm.

15. An integrated circuit formed by the method of claim 10.

16. A method, comprising:
attaching a tape substrate to a side of a semiconductor die having a set of conductive bumps extending from the side of the die, wherein the tape substrate comprises a tape layer, a solder mask, a set of vias, and a set of leads, in which a via of the set of vias is coupled between the conductive bump and a lead of the set of leads, and the solder mask surrounds the set of vias in a respective layer of the tape substrate; and
applying a molding compound to the tape substrate and a top side of the semiconductor die to provide a packaged semiconductor device.

17. The method of claim 16, wherein the tape layer is a polyimide layer.

18. The method of claim 16, wherein a thickness of the solder mask is between 90% of a thickness of the tape layer and 110% of the thickness of the tape layer.

19. The method of claim 16, wherein the tape layer has a breakdown voltage greater than 300 V/μm.

20. The method of claim 16, further comprising forming the tape substrate.

21. The method of claim 19, wherein forming the tape substrate comprises:
attaching a first side of an adhesive to a side of a tape that comprises the tape layer;
forming sprocket holes and via holes through the adhesive and the tape;
laminating a first side of a copper layer onto a second side of the adhesive; and
etching exposed portions of the first side of the copper layer through the via holes.

22. The method of claim 21, wherein forming the tape substrate further comprises:
attaching a masking material to the copper layer;
forming copper vias in the via holes, wherein the copper vias comprise the set of vias;
removing the masking material;
patterning the copper layer to expose portions of the adhesive layer and form a set of islands from the copper layer;
printing a solder mask on the exposed portions of the adhesive layer and on the set of islands; and
plating exposed portions of the set of islands to form leads that comprise the set of leads.

23. The method of claim 22, wherein forming the tape substrate further comprises:
punching through holes through the tape;
separating the tape into a set of strips; and
cutting a strip of the set of strips into a set of tape substrate segments, wherein a tape substrate segment of the set of tape substrate segments comprises the tape substrate.

24. An integrated circuit formed by the method of claim 16.
